(19) United States
(12) Patent Application Publication
(10) Pub. No.: US 2024/0038617 A1
(43) Pub. Date: Feb. 1, 2024

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Wensen Hung, Hsinchu County (TW); Jia-Syuan Li, Taoyuan City (TW); Tsung-Yu Chen, Hsinchu City (TW)

(73) Assignee: Taiwan Semiconductor Manufacturing Company, Ltd., Hsinchu (TW)

(21) Appl. No.: 17/874,192

(22) Filed: Jul. 26, 2022

(51) Int. Cl. H01L 23/367; H01L 23/053; H01L 23/42; H01L 21/52; H01L 23/00

(52) U.S. Cl. CPC H01L 23/367; H01L 23/053; H01L 23/42; H01L 21/52; H01L 24/32; H01L 2224/32245

(57) ABSTRACT

A package structure includes a substrate, a semiconductor package disposed over the substrate, a first lid structure disposed over the substrate, and a second lid structure disposed over the semiconductor package and the first lid structure. The first lid structure includes an opening exposing a region of the semiconductor package. A thermal interface material is disposed between the second lid structure and the semiconductor package, and a phase change adhesive is disposed between the second lid structure and the first lid structure.

### BACKGROUND

In the packaging of integrated circuits, semiconductor dies may be stacked through bonding, and may be bonded to other package components such as interposers and package substrates. The resulting packages are known as Three-Dimensional Integrated Circuits (3DICs). Heat dissipation is a challenge in the 3DICs. There exists a bottleneck in efficiently dissipating the heat generated in the inner dies of the 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view showing a package structure in accordance with some embodiments of the disclosure.

FIG. 2 is a schematic perspective view showing a portion of package structure shown in FIG. 1 in accordance with some embodiments of the disclosure.

FIG. 3 through FIG. 6 are schematic cross-sectional views of various stages in a manufacturing method of a package structure in accordance with some embodiments of the disclosure.

FIG. 7 and FIG. 8 are schematic cross-sectional views of various stages in a manufacturing method of a package structure in accordance with some embodiments of the disclosure.

FIG. 9 is a schematic cross-sectional view showing a package structure in accordance with some embodiments of the disclosure.

FIG. 10 is a schematic cross-sectional view showing a package structure in accordance with some embodiments of the disclosure.

FIG. 11 is a schematic cross-sectional view showing a package structure in accordance with some embodiments of the disclosure.

FIG. 12 is a schematic cross-sectional view showing a package structure in accordance with some embodiments of the disclosure.

FIG. 13 is a schematic cross-sectional view showing a package structure in accordance with some embodiments of the disclosure.

FIG. 14 is a schematic top view showing a package structure shown in FIG. 13 in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments of the present disclosure provide package structures with two-piece lid structure for better thermal performance (e.g., heat dissipation) in High Performance Computing (HPC) applications which requires extreme high power and high power density at die regions. The two-piece lid structure includes a mechanical enhanced lid attached to the substrate and a thermal enhanced lid attached to the package components. By implementing two-piece lid structure, the mechanical and thermal performances of the package structure can be co-optimized.

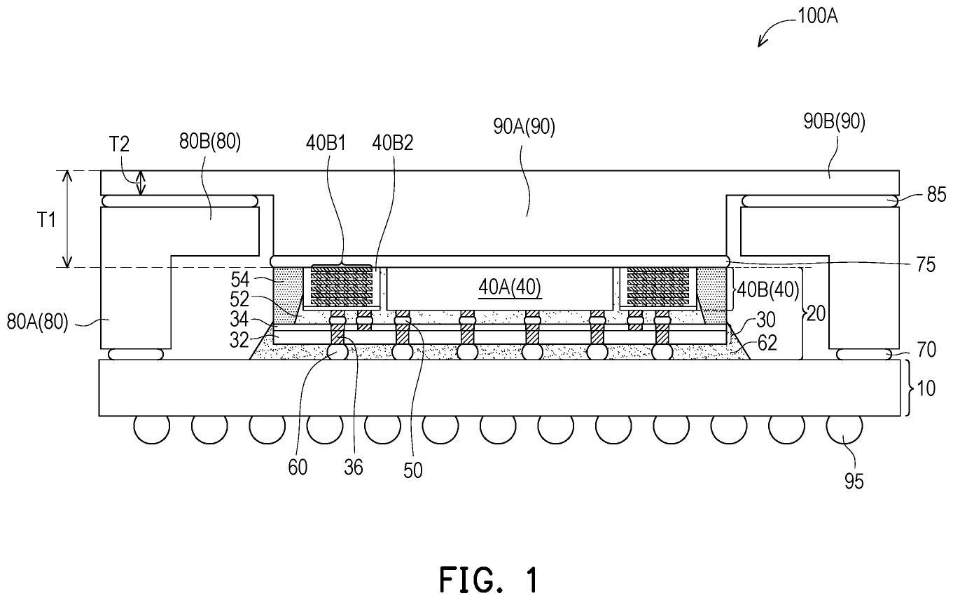

The various aspects of the present disclosure will now be described in more detail with reference to the figures. FIG. 1 is a schematic cross-sectional view showing a package structure 100A in accordance with some embodiments of the disclosure.

As shown in FIG. 1, the package structure 100A includes a substrate 10 and a package 20 placed on the substrate 10. In some embodiments, the substrate 10 is a package substrate strip including a plurality of package substrates therein. Package substrates may be cored package substrates including cores, or may be core-less package substrates that do not have cores therein. In alternative embodiments, the substrate 10 is an interposer wafer, a printed circuit board, a reconstructed wafer, or the like. Further, the substrate 10 is free from (or includes) active devices such as transistors and diodes therein, in accordance with some embodiments. In some embodiments, the substrate 10 is also free from (or includes) passive devices such as capacitors, inductors, resistors, or the like therein.

In some embodiments, the substrate 10 includes a plurality of dielectric layers (not specifically shown). For example, the plurality of dielectric layers includes a core dielectric layer, and an upper dielectric layer and a lower dielectric layer respectively over and under the core dielectric layer. In some embodiments, the upper and lower dielectric layers are formed of dry films such as Ajinomoto Build-up Films (ABFs). In alternative embodiments, the upper and lower dielectric layers are formed of or comprise polybenzoxazole (PBO), polyimide, benzocyclobutene (BCB), or the like. In some embodiments, the core dielectric layer is formed of epoxy, resin, glass fiber, prepreg (which comprises epoxy, resin, and/or glass fiber), glass, molding compound, plastic, combinations thereof, and/or multi-layers thereof. In some alternative embodiments, the core dielectric layer is formed of polymers such as PBO, polyimide, BCB, or the like. In addition, the core dielectric layer includes a redistribution structure such as metal lines/pads and vias, which are functioned as through-substrate connection, in accordance with some embodiments.

Further referring to FIG. 1, a package 20 is placed on the substrate 10. In some embodiments, the package 20 includes device dies therein, and may include other package components such as interposers, packages, die stacks, or the like. For example, the package 20 includes package components 30, 40A, and 40B, as seen in FIG. 1. In some embodiments, package component 30 is interposer that includes a substrate 32 and a corresponding dielectric layer 34 over the substrate 32. Accordingly, the package component 30 may also be referred to as an interposer. It is understood that the structure of the package component 30 shown in FIG. 1 is merely exemplary, and the details such as the plurality of dielectric layers on the top side and bottom side of substrate 32, metal lines and vias, metal pads, or the like, are not shown. A plurality of through-substrate vias 36 (sometimes referred to as through-silicon vias 36 when the substrate 32 is a silicon substrate) penetrates through the substrate 32, as illustrated in FIG. 1. In some embodiments, through-substrate vias 36 are used to electrically interconnect the conductive features on the top side and the bottom side of substrate 32 to each other.

In some embodiments, the package components 40A and 40B are bonded to the respective underlying package component 30. In FIG. 1, one package component 40A and two package components 40B are illustrated and are bonded to the same package component 30; however, any number of the package components 40A or 40B can be bonded to one package component 30, and can be in any arrangement. In some embodiments, the package components 40A and 40B are different types of package components, and are collectively referred to as package components 40.

In some embodiments, each of the package components 40 includes a device die, a package with a device die(s) packaged therein, a System-on-Chip (SoC) die including a plurality of integrated circuits (or device dies) integrated as a system, or the like. The device dies in the package components 40 may be or may include logic dies, memory dies, input-output dies, Integrated Passive Devices (IPDs), or the like, or combinations thereof. For example, the logic device dies in the package components are Central Processing Unit (CPU) dies, Graphic Processing Unit (GPU) dies, mobile application dies, Micro Control Unit (MCU) dies, BaseBand (BB) dies, Application processor (AP) dies, or the like. In some embodiments, the memory dies in the package components 40 include Static Random Access Memory (SRAM) dies, Dynamic Random Access Memory (DRAM) dies, or the like. In some other embodiments, the device dies in the package components 40 include semiconductor substrates and interconnect structures.

In the subsequent discussion in accordance with some example embodiments, the package components 40A are referred to as device dies, which may be SoC dies, and the package components 40B are memory stacks such as High-Performance Memory (HBM) stacks. As shown in FIG. 1, the package components 40B include memory dies forming a die stack, and an encapsulant 40B2 (such as a molding compound) encapsulating the memory dies 40B1 therein. When viewed from top, the encapsulant may form a ring encircling the memory dies 40B1, and may also extend into the gaps between the memory dies 40B1.

As shown in FIG. 1, the package components 40 are bonded to the underlying package component 30, for example, through solder regions 50, and an underfill 52 is dispensed between the package components 40 and the underlying package component 30. In some embodiments, the package components 40 are bonded to the package component 30 through a Chip-on-Wafer (CoW) bonding process. For example, the package components 40, which are discrete chips/packages, are bonded to the package components 30 that are in an unsawed wafer to form a reconstructed wafer. After the dispensing of the underfills 52, an encapsulant 54, such as a molding compound, is applied to encapsulate the package components 40. A planarization process is then performed on the encapsulant 54 to level a top surface of the encapsulant 54 with top surfaces of the package components 40. A reconstructed wafer is thus formed, and is then sawed apart to form the discrete package 20.

In some embodiments, the package 20 is bonded to substrate 10 through solder regions 60 underlying and joined to the interposer 30. For example, the solder regions 60 are reflowed after the placement of the package 20 onto the substrate 10. An underfill 62 is then dispensed between the gap between the package 20 and the substrate 10. In some embodiments, the solder regions 60 include Ball Grid Array (BGA) balls. However, other bonding schemes such as metal-to-metal direct bonding, hybrid bonding, or the like, may also be used for bonding the package component 30 to the substrate 10.

Still referring to FIG. 1, the package structure 100A further includes a two-piece lid structure placed on the substrate 10 and the package 20. For example, the two-piece lid structure includes a lower lid 80 and an upper lid 90 attached to the lower lid 80. As seen from FIG. 1, the lower lid 80 is directly over the substrate 10 and attached to the substrate 10 through adhesives 70. In some embodiments, the lower lid 80 is used to compensate stress on the substrate 10, such that a better coplanarity (COP) of the substrate 10 can be achieved (i.e., the flatness of the substrate is improved). Accordingly, the lower lid 80 may also be referred to as a mechanical enhanced lid 80. In FIG. 1, the upper lid 90 is attached to the package 20 through a Thermal Interface Material (TIM) 75 and attached to the lower lid 80 through a phase change adhesive (PCA) 85. In some embodiments, the upper lid 90 is used to dissipating or spreading the heat generated by the package components 40A and 40B, thus the upper lid 90 may also be referred to as a thermal enhanced lid 90. Alternatively, the upper lid 90 in contact with the phase change adhesive 85 may be referred to as a compressible lid owing to the compressibility from the phase change adhesive 85 at high temperature.

In some embodiments, the lower lid 80 and the upper lid 90 are respectively formed from a material selected from copper, aluminum, cobalt, nickel-coated copper, stainless steel, tungsten, copper-tungsten, copper-molybdenum, copper carbon composite, silver diamond composite (AgD), copper diamond composite (CuD), metal diamond composites, aluminum nitride, aluminum silicon carbide, alloy 42, or the like. In alternative embodiments, the lower lid 80 includes material having lower coefficient of thermal expansion (CTE), such as stainless steel SUS430, Alloy42, Invar, Covar, for compensation of CTE mismatch, such that the coplanarity of the package structure can be improved.

In some other embodiments, the lower lid 80 and the upper lid 90 are further respectively coated with another metal, such as gold, nickel, titanium gold alloy, lead, tin, nickel vanadium, or the like. In alternative embodiments, the upper lid 90 includes material having higher thermal conductivity, such as copper, copper diamond composite, silver diamond composite, or vaper chamber lid, to achieve better steady state and transient heat dissipation without placing too much stress on the TIM 75. In some embodiments, the upper lid 90 includes a material different from that of the lower lid 80. Generally, the upper lid 90 (i.e., the thermal enhanced lid) may include a material having higher thermal conductivity than that of the material used for the lower lid 80. For example, a thermal conductivity of the material of the upper lid 90 may be about two times greater than that of the material of the lower lid 80. In one embodiment, the lower lid 80 includes copper and the upper lid 90 includes copper diamond composite. Alternatively, the upper lid 90 and the lower lid 80 may include same material.

In some embodiments, a material of the adhesive 70 includes thermally conductive adhesive, silicone-based adhesive, epoxy resin-based adhesive, or the like, or includes rubber based-content with curing promoting material. In some embodiments, the TIM 75 includes a base material and filler particles mixed in the base material. The base material may be a polymer-based material, an epoxy-based material, a resin-based material, or the like. For example, the base material is selected from an olefin copolymer, an acrylic copolymer, a polyimide-based material, a PBO-based material, a silicone-based material, the mixture thereof, or the like. The filler particles may include thermal conductive material such as aluminum oxide, boron nitride, aluminum nitride, aluminum, copper, silver, indium, the like, or a combination thereof. In some embodiments, the TIM 75 is a film-type or sheet-type TIM, such as a carbon nanotube (CNT) sheet or a graphite sheet, which is pre-formed. In some other embodiments, the TIM 75 is a gel-type TIM. Alternatively, the TIM 75 may be a liquid metal, a metal pad or the like that includes metallic material. The TIM 75 has a thermal conductivity value that is higher than that of the adhesives 70, in accordance with some embodiments.

In some embodiments, the phase change adhesive 85 includes a material that changes phase (for example, from a solid state to a quasi-liquid state) at a relatively low phase change temperature, such as around 40° C. to 60° C. The phase change material for the phase change adhesive 85 may include a based material and filler particles mixed in the base material. In one embodiment, the phase change adhesive 85 includes a polymer-based material and aluminum filler particles. In some embodiments, the phase change adhesive 85 may be applied in a film-type or a pad-type. Further, in some embodiments, the phase change adhesive 85 has a thermal conductivity value between those of the adhesive 70 and the TIM 75.

As shown in FIG. 1, the package structure 100A further includes solder regions 95 that are underlying and joined to the substrate 10. The solder regions 95 may include BGA ball and may be used to electrically connect the package structure 100A (e.g., CoWoS package structure) to a motherboard (not shown) or another device component of an electrical system.

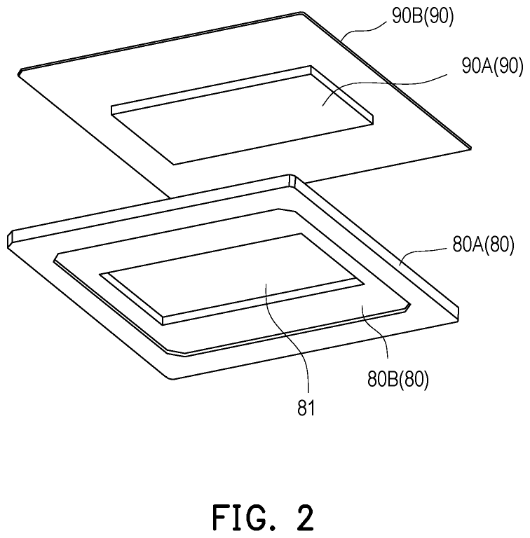

FIG. 2 is a schematic perspective view showing two-piece lid structure (i.e., the lower lid 80 and the upper lid 90) of the package structure 100A shown in FIG. 1 in accordance with some embodiments of the disclosure. Referring to FIG. 1 and FIG. 2 together, the structures of the lower lid 80 and the upper lid 90 will be described below in greater detail. As shown in FIG. 1, the lower lid 80 includes an outer peripheral portion 80A extending down to join adhesives 70, and an inner peripheral portion 80B connecting to the outer peripheral portion 80A and extending inwards (e.g., to the center of the package structure 100A) from the outer peripheral portion 80A. In some embodiments, a thickness of the inner peripheral portion 80B is less than a thickness of the outer peripheral portion 80A, and a bottom surface of the inner peripheral portion 80B is above a top surface of the package 20. As seen from FIG. 2, both outer peripheral portion 80A and inner peripheral portion 80B forma a full ring encircling the package 20. Furthermore, the inner peripheral portion 80B defines (e.g., delimits) an opening 81 that exposes the package 20 (see FIG. 1). In other words, an orthogonal projection of the opening 81 may overlap (or cover) a region of package components 40B of the package 20. Although the opening 81 is illustrated having a square shape, the opening 81 may has other different shapes.

In some embodiments, the upper lid 90 includes a central portion 90A and an outer portion 90B that connects to the central portion 90A. As illustrated in FIG. 1, the central portion 90A is placed right above the package 20 and is further fit right into the opening 81 of the lower lid 80, and the outer portion 90B is placed above and covers the lower lid 80. In some embodiments, a bottom surface of the central portion 90A is in direct contact with the TIM 75, and a bottom surface of the outer portion 90B is in direct contact with the phase change adhesive 85. As seen from FIG. 2, the outer portion 90B forms a ring-shaped structure encircling the central portion 90A, and a thickness T1 of the central portion 90A is greater than a thickness T2 of the outer portion 90B.

As described above in relation to FIG. 1 and FIG. 2, a two-piece lid structure including a mechanical enhanced lid (i.e., the lower lid 80) and a thermal enhanced lid (i.e., the upper lid 90) is used in the package structure 100A. By dividing the lid into two discrete lids according to their functional uses, the thermal and mechanical properties of the package structure can be co-optimized, thus a better design or fabrication flexibility can be achieved. For example, the mechanical enhanced lid is attached to the substrate for stress compensation and warpage optimization, and the thermal enhanced lid is located above the package component (e.g., device dies) and in contact with and is thermally coupled to the TIM for heat spreading.

Further, a phase change adhesive is used to attach the mechanical enhanced lid and the thermal enhanced lid together; for example, an outer portion of the thermal enhanced lid is attached to the underlying mechanical enhanced lid through the phase change adhesive. During the function of the device dies in the package, the state of the phase change material may change with temperature and further act as a stress buffer layer to alleviate the unwanted stress caused by CTE mismatch within the whole package. As a result, the thermal enhanced lid (e.g., the central portion right above the die area) can be uniformly press to the TIM while external system heat sink mounted on top of the package, such that a better contact between the TIM and the thermal enhanced lid and between the TIM and the package can be obtained for more effective heat dissipation. In addition, a thickness of the TIM may be thinner due to the uniform pressing from the thermal enhanced lid to the TIM, such that the thermal resistance (TR) can be further reduced. On the other hand, the warpage reduction contributed by the mechanical enhanced lid can also improve the contact between the TIM and the thermal enhanced lid and between the TIM and the package.

With the two-piece lid structure, the thermal resistance of the package structure may be reduced by about 20%-80%, in accordance with some embodiments. For example, in embodiments where the TIM 75 is film-type TIM such as CNT sheet, the thermal resistance of the package structure may be reduced by about 20%-60%. In embodiments where the TIM 75 includes liquid metal, the thermal resistance of the package structure may be reduced by about 70%-80%. It is noted that the thermal performance (e.g., thermal resistance) of the entire package 20 is enhanced. That is, the thermal resistances of both center and edges (or corners) of the package 20 are greatly reduced.

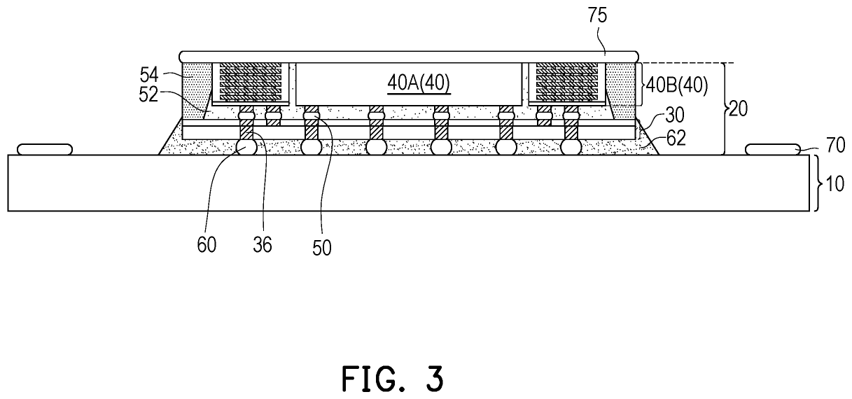

FIG. 3 through FIG. 6 are schematic cross-sectional views of various stages in a manufacturing method of the package structure 100A shown in FIG. 1 in accordance with some embodiments of the disclosure. It is understood that additional operations can be provided before, during, and after processes shown by FIG. 3 through FIG. 6, and some of the operations described below can be replaced or eliminated, for additional embodiments of the method. The order of the operations/processes may be interchangeable.

Referring to FIG. 3, the package 20 is mounted on the substrate 10. As described above with reference to FIG. 1, the package 20 includes multiple package components, such as the interposer 30 and the device dies 40A, 40B that are bonded to the interposer 30. In illustrated embodiments, one device die 40A (for example, a SoC die) is arranged in a center region of the interposer 30, and a pair of device dies 40B (for example, HBM dies) is arranged in an outer region of the interposer 30 next to the device die 40A. The aforementioned arrangement is merely examples, and the arrangement of the device die can be different according to the design requirements. The device dies 40A, 40B are electrically connected to the interposer 30 through the solder regions 50, and the solder regions 50 and portions of the device dies 40A, 40B are surrounded by the underfill 52. The device dies 40A, 40B, the solder regions 50, and the underfill 52 are encapsulated by the encapsulant 54. In some embodiments, opposite sidewalls of the encapsulant 54 are aligned with opposite sidewalls of the interposer 30.

As shown in FIG. 3, the package 20 is bonded to the substrate 10 through the solder regions 60, and the gap between the packages 20 and substrate 10 are filled by the underfill 62. After the bonding of the package 20 to the substrate 10, adhesives 70 is dispensed onto a top surface of the substrate 10. In some embodiments, the adhesives 70 are dispensed as a ring encircling the package 20, or are dispensed as discrete portions aligning to a ring.

Next, the TIM 75 is applied to the package 20, in accordance with some embodiments. For example, in embodiments where the TIM 75 is a film-type TIM (which is a pre-formed solid TIM), the TIM 75 is attached through picking and placing. In embodiments where the TIM 75 is a liquid-type or gel-type TIMs, the TIM 75 is dispensed in a flowable form and then cured into solid. In embodiments where the TIM 75 is a soft film, the TIM 75 is rolled to the intended place, and is then pushed toward the package 20. As illustrated in FIG. 3, the TIM 75 is in contact with a top surface of the package 20 (i.e., top surfaces of the device dies 40A, 40B and the encapsulant 54). In other words, the TIM 75 overlaps with the package 20 and has a same top-view size and a top-view area as the corresponding underlying package 20.

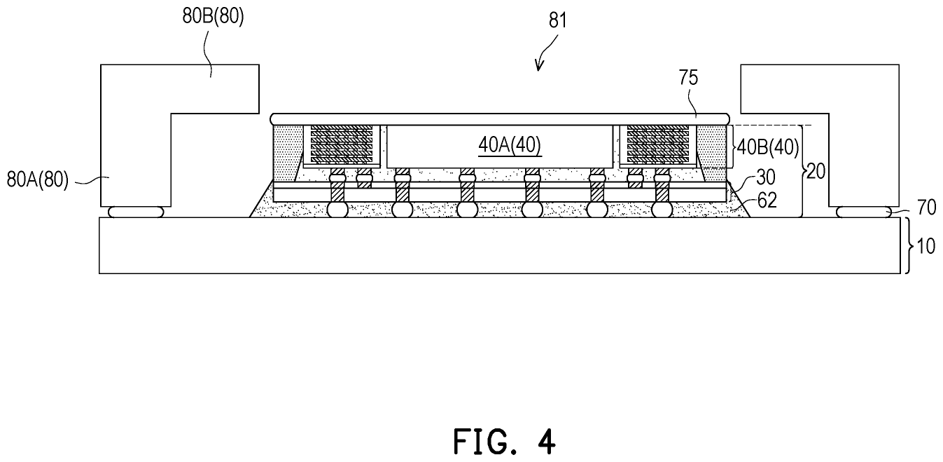

Referring to FIG. 4, the lower lid 80 is attached to adhesives 70 on the substrate 10. As shown in FIG. 4 and as described above with reference to FIG. 1, the lower lid 80 has a ring-shaped structure, and the lower lid 80 includes the outer peripheral portion 80A and the inner peripheral portion 80B extending from the outer peripheral portion 80A in the direction towards the package 20. During the attachment of the lower lid 80, the lower lid 80 is pushed down against adhesives 70 to ensure the physical contact between these features. For example, the outer peripheral portion 80A is in direct contact with the adhesives 70. Further, the opening 81 defined by the inner peripheral portion 80B exposes a region of the package 20 (e.g., a region of the device dies 40A, 40B), in which a top surface of the TIM 75 is entirely exposed by the opening.

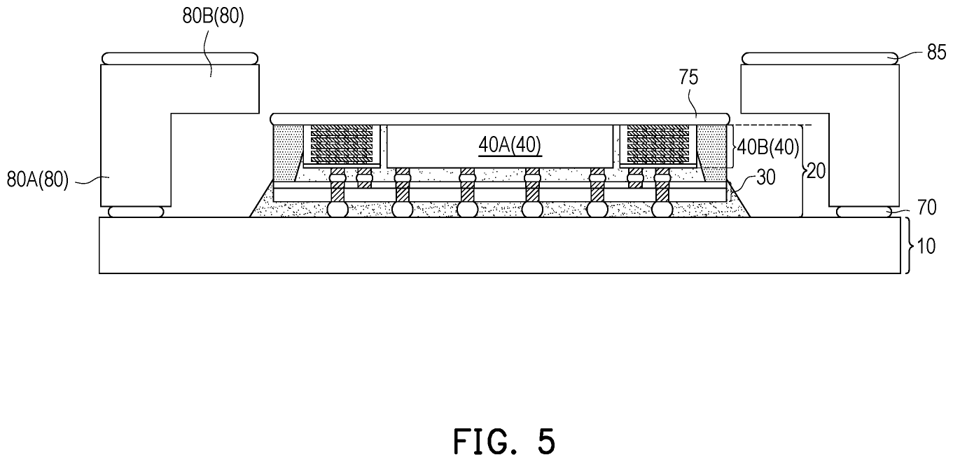

Referring to FIG. 5, the phase change adhesive 85 is dispensed on top surfaces of the peripheral portion 80A and the inner peripheral portion 80B. In some embodiments, the phase change adhesive 85 covers the top surface of the lower lid 80 after the dispensing process.

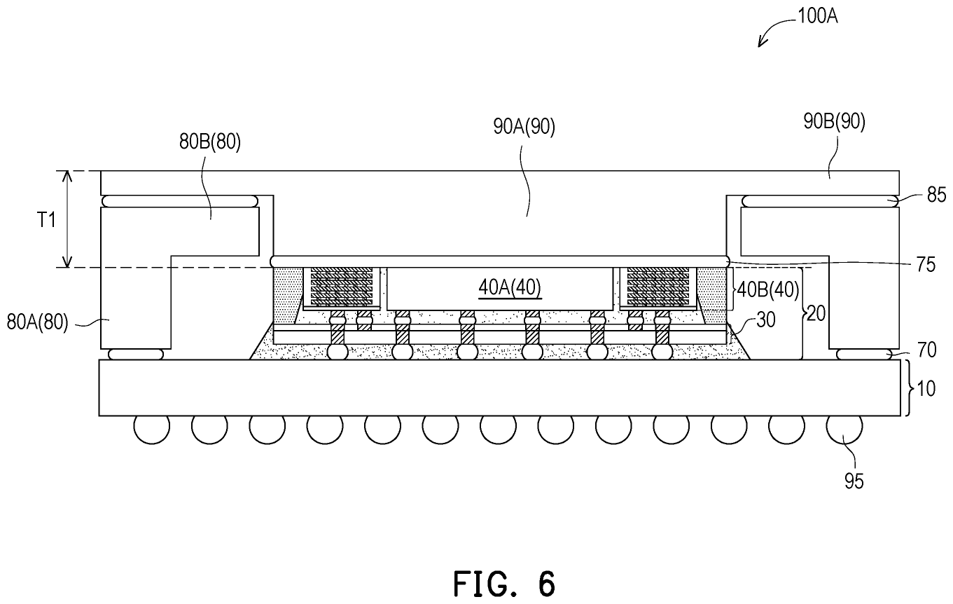

Referring to FIG. 6, the upper lid 90 is attached to the lower lid 80 and to the package 20. For example, the central portion 90A of the upper lid 90 is attached to the package 20 through the TIM 75, and the outer portion 90B of the upper lid 90 is attached to the lower lid 80 through the phase change adhesive 85. During the attachment of the upper lid 90, the upper lid 90 is pushed down against the TIM 75 at the central portion 90A and against the phase change adhesive 85 at the outer portion 90B to ensure the physical contact to these features.

As illustrated in FIG. 6, the central portion 90A is placed fitting right in the opening 81 defined by the lower lid 80, and opposite sidewalls of the central portion 90A are spaced apart from the respective inner sidewall of the inner peripheral portion 80B of the lower lid. That is, the lower lid 80 and the upper lid 90 are substantially separate from each other. In some embodiments, a lateral distance of the central portion 90A of the upper lid is substantially the same as a lateral distance of the TIM 75 and a lateral distance of the package 20 for better heat dissipation.

A curing process is then performed to solidify the adhesive 70, the TIM 75 (when the TIM 75 is gel-type or liquid-type TIM), and the phase change adhesive 85. During the curing process, the adhesive 70, the TIM 75, and the phase change adhesive 85 may be cured and hardened, such that the adhesion of the adhesive 70 to the lower lid 80, the adhesion of the TIM 75 and the phase change adhesive 85 to the upper lid 90 are improved. In accordance with some embodiments, the curing process includes a thermal curing process, which is performed at a temperature in a range between about 120° C. and about 180° C. The curing duration may be in the range between about 5 minutes and about 30 minutes, thus the curing process may be referred to as snab curing process. Although a single curing process for the adhesive 70, the TIM 75, and the phase change adhesive 85 is described above, the adhesive 70, the TIM 75, and the phase change adhesive 85 can be separately cured using multiple curing processes, in accordance with some embodiments. Later, the solder regions 95 may be placed on the substrate 10, and then reflowed. The resulting structure is shown in FIG. 6.

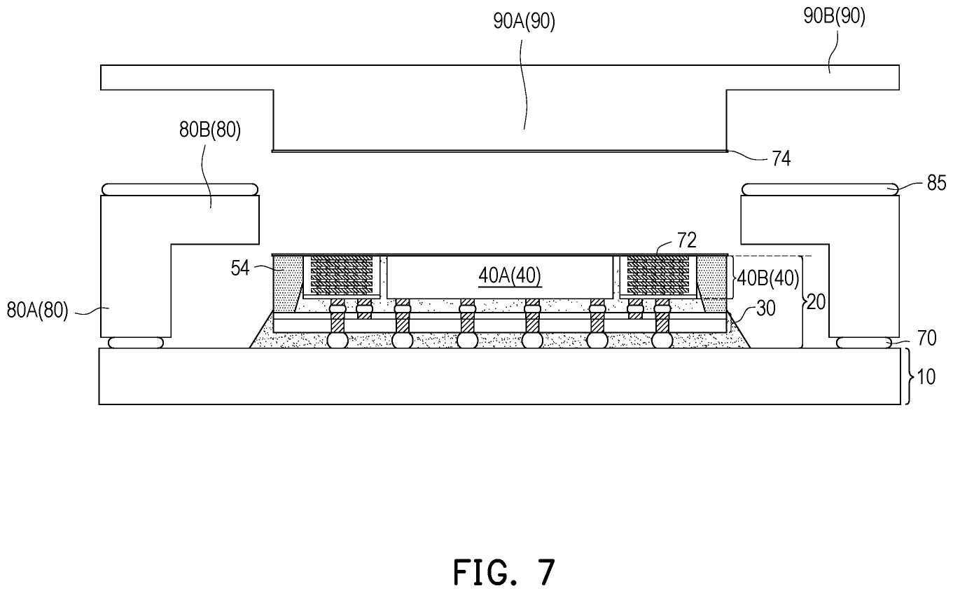

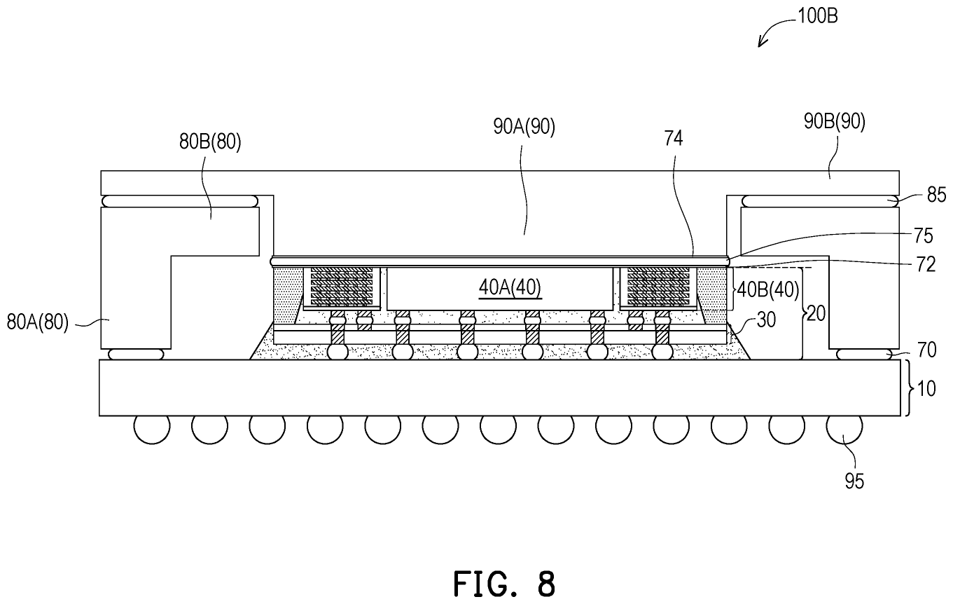

FIG. 7 and FIG. 8 are schematic cross-sectional views of various stages in a manufacturing method of a package structure 100B in accordance with some embodiments of the disclosure. It is understood that additional operations can be provided before, during, and after processes shown by FIG. 7 and FIG. 8, and some of the operations described below can be replaced or eliminated, for additional embodiments of the method. The order of the operations/processes may be interchangeable.

The manufacturing method of the package structure 100B is similar to that of the package structure 100A and only differences are discussed below. The difference between the package structure 100A and the package structure lies in that the TIM 75 used in the package structure 100B includes metal TIM, such as indium foil, phase change liquid metal pad, liquid metal, phase change gel, or the like. In such embodiments, subsequent to the attachment of the lower lid 80 to the substrate 10, a back side metallization (BSM) structure 702 and a back side metallization 704 are first respectively formed on the top surface of the package 20 and on the bottom surface of the central portion 90A of the upper lid 90.

As illustrated in FIG. 7, the back side metallization structure 702 is formed covering the device dies 40A, 40B and the encapsulant 54, and the back side metallization structure 704 is formed covering the central portion 90A of the upper lid 90. In some embodiments, the back side metallization structure 702 includes different material with the back side metallization structure 704. For example, the back side metallization structure 702 includes metal alloy such as, Ti/Au, Ti/Cu/NiV/Al, Ti/Ni/Ag, Ti/Ni/Ti/Ag, Ti/Ni/Ag/Ni, Ti/Ni/Ag/Sn, or the like. In some embodiments, the back side metallization structure 704 includes metal alloy such as Ni/Au, or the like. Alternatively, the back side metallization structure 702 may be similar to or substantially the same as the back side metallization structure 704.

Next, the phase change adhesive 85 is dispensed on the lower lid 80, the material used for the phase change adhesive 85 is as discussed above and thus not repeated herein. A metal TIM for the TIM 75 may be attached directly on the back side metallization structure 702. Depending on the types of the TIM, the TIM 75 (i.e., metal TIM) may be attached to the back side metallization structure 702 through picking and placing or dispensing process. The upper lid 90 is then pushed down against the TIM 75 and the phase change adhesive 85, followed by a possible curing process to attach the upper lid 90 to the lower lid 80 and the package 20. As shown in FIG. 8, the TIM 75 is sandwiched between the back side metallization structure 702 and the back side metallization structure 704. Later, the solder regions 95 may be placed on the substrate 10, and then reflowed. The resulting structure is shown in FIG. 8.

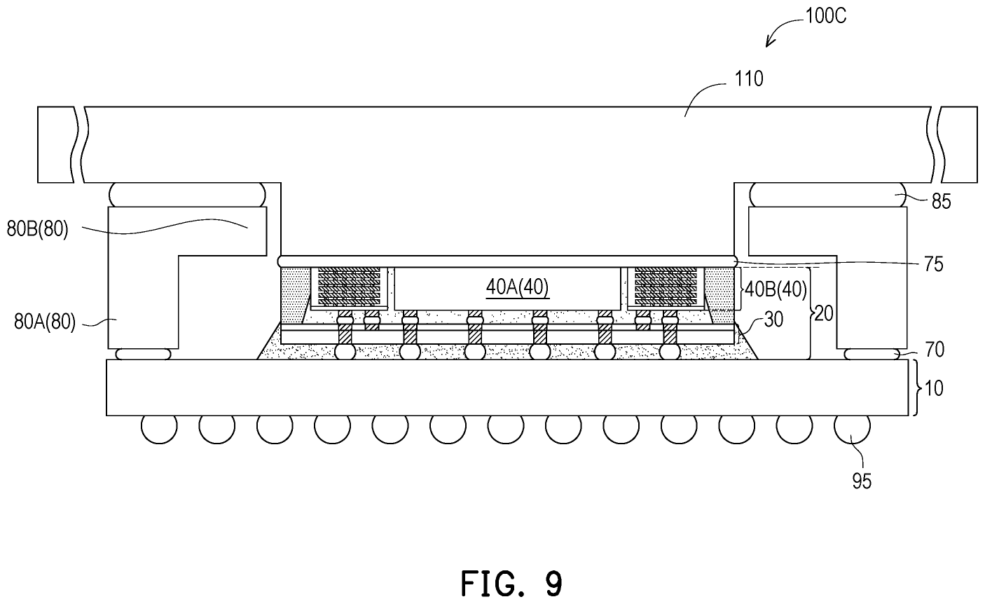

FIG. 9 is a schematic cross-sectional view showing a package structure 100C in accordance with some embodiments of the disclosure. The package structure 100C is similar to the package structure 100A with reference to FIG. 1. The difference between the two lies in that a heat sink 110 is attached to the lower lid 80 and to the package 20. The heat sink 110 may include a fan (not shown) to assist heat spreading or cooling. In some embodiments, the heat sink includes similar structure as the upper lid 90 of the package structure 100A that is fit in the opening defined by the lower lid to contact and thermally couple the TIM 75 over the package 20.

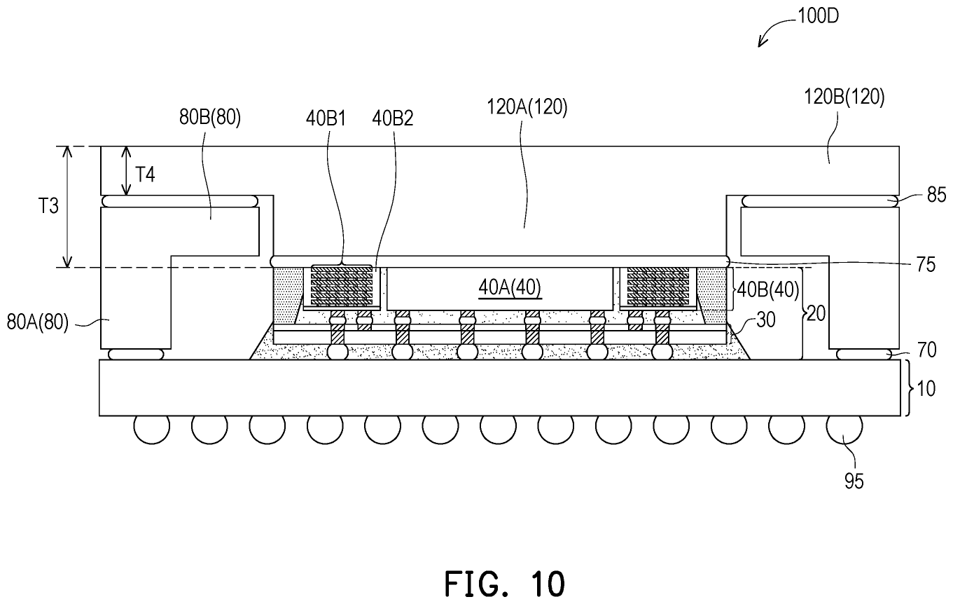

FIG. 10 is a schematic cross-sectional view showing a package structure 100D in accordance with some embodiments of the disclosure. The package structure 100D is similar to the package structure 100A with reference to FIG. 1. The difference between the two lies in that the upper lid 120 of the package structure 100D is thicker than the upper lid 90 of the package structure 100A. As shown in FIG. 10, a thickness T3 of the central portion 120A of the upper lid 120 is greater than the thickness T1 of the central portion 90A of the upper lid 90, and a thickness T4 of the outer portion 120B of the upper lid 120 is greater than the thickness T2 of the outer portion 90B of the upper lid 90. The thicker upper lid 120 provides a larger thermal mass for more effective heat spreading, which is good for enhancing thermal performance at hot spots (for example, heat dissipation at regions of high power density or device with high current spike workload) of the device dies.

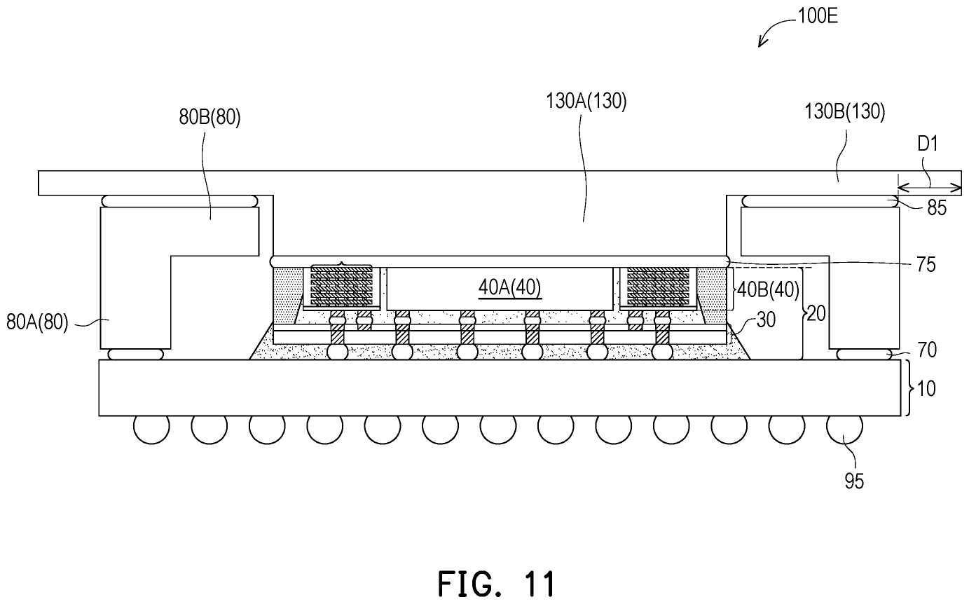

FIG. 11 is a schematic cross-sectional view showing a package structure 100E in accordance with some embodiments of the disclosure. The package structure 100E is similar to the package structure 100A with reference to FIG. 1. The difference between the two lies in that the outer portion 130B of the upper lid 130 of the package structure 100E is extending beyond outer sidewalls of the lower lid 80 by a distance D1, as shown in FIG. 11. In other words, the outer portion 130B includes an overhang portion (not labeled) extends past outer sidewalls of the lower lid 80. Similarly, the outer portion 130B with overhang portions also provides a larger thermal mass that is good for heat spreading at high power and high power density device dies in the package structure.

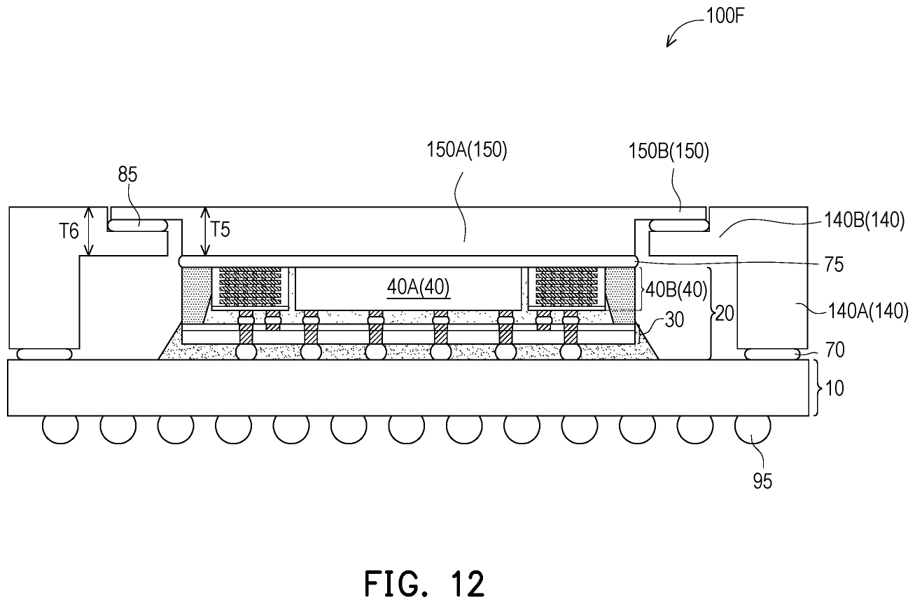

FIG. 12 is a schematic cross-sectional view showing a package structure 100F in accordance with some embodiments of the disclosure. The package structure 100F is similar to the package structure 100A with reference to FIG. 1. The difference between the two is that the upper lid 150 is fully fit in the lower lid 140 in the package structure 100F. As shown in FIG. 12, the lower lid 140 includes an outer peripheral portion 140A and an inner peripheral portion 140B connecting to the outer peripheral portion 140A, and the upper lid 150 includes a central portion 150A and an outer portion 150B connecting to the central portion 150A. In some embodiments, the inner peripheral portion 140B includes a recess (not labeled), and the outer portion 150B of the upper lid 150 is fit right into the recess of the inner peripheral portion 140B of the lower lid 140. As a result, a top surface of the upper lid 150 is level to a top surface of the lower lid 140, as illustrated in FIG. 12. In other words, an overall thickness T5 of the upper lid 150 is substantially the same as a thickness T6 of the outer peripheral portion 140A of the lower lid. Such lid structures may be suitable for package structures where a thinner package thickness is required as the modern packages shrink in size.

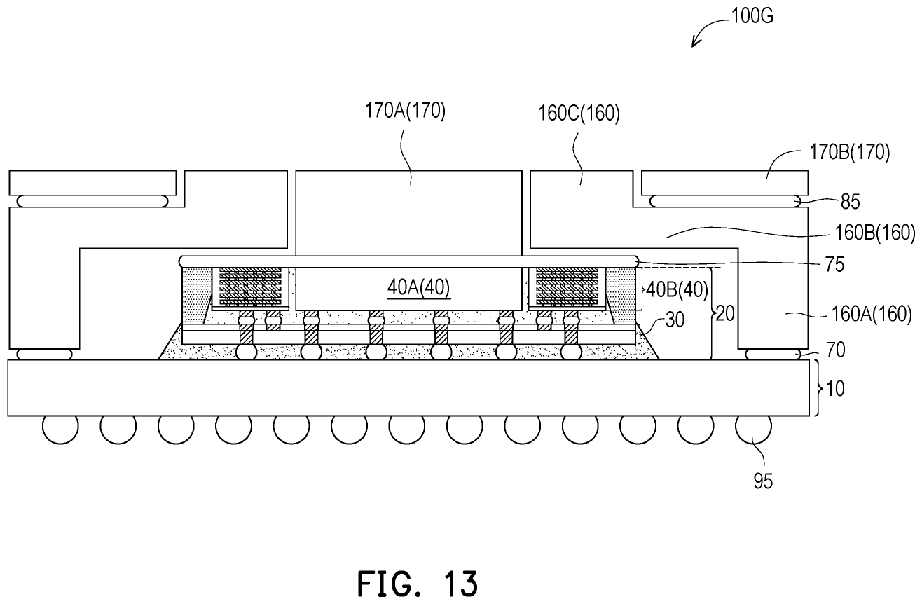

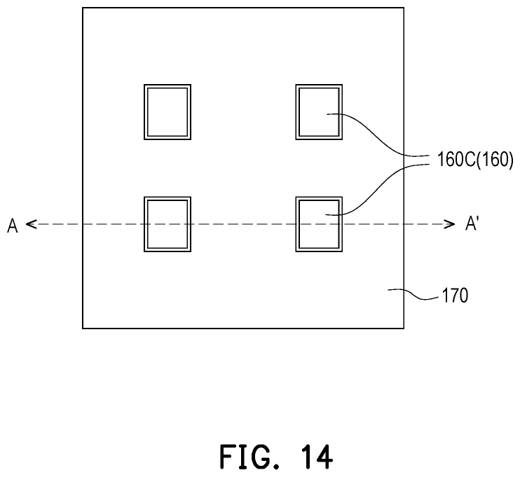

FIG. 13 is a schematic cross-sectional view showing a package structure 100G in accordance with some embodiments of the disclosure. FIG. 14 is a schematic top view showing the package structure 100G shown in FIG. 13 in accordance with some embodiments of the disclosure. In some embodiments, the cross-sectional view shown in FIG. 13 is taken along line A-A′ of FIG. 14.

The package structure 100G is similar to the package structure 100A with reference to FIG. 1. The difference between the two is that the lower lid 160 further includes a protruding portion 160C in the package structure 100G. For example, as illustrated in FIG. 13 and FIG. 14, the protruding portion 160C connects to the inner peripheral portion 160B and protrudes upwards between the central portion 170A of the upper lid 170 and the outer portion 170B of the upper lid 170. In some embodiments, the protruding portion 160C is located over the device dies (for example, memory dies) that generate less heat compared to the high power device dies.

On the other hand, the central portion 170A of the upper lid 170 only contacts and thermally couples the TIM 75 at a region of the high power device dies, as shown in FIG. 13. Therefore, a lateral dimension of the opening (i.e., where the central portion 170A is fit) defined by the protruding portion 160C is smaller than that of the opening 81 of the lower lid 80 of the package structure 100A shown in FIG. 1. That is, the protruding portion 160C reduces the size or area of the opening, and thus provides an increased mechanical strength for the package to against warpage. It is understood that the arrangement and amount of the protruding portion 160C illustrated in FIG. 13 and FIG. 14 are merely examples and can be adjusted depending on the design requirements.

In accordance with an embodiment of the disclosure, a package structure is described. The package structure includes a substrate, a semiconductor package disposed over the substrate, a first lid structure disposed over the substrate, and a second lid structure disposed over the semiconductor package and the first lid structure. The first lid structure includes an opening exposing a region of the semiconductor package. A thermal interface material is disposed between the second lid structure and the semiconductor package, and a phase change adhesive is disposed between the second lid structure and the first lid structure.

In accordance with an embodiment of the disclosure, a structure is described. The structure includes a package substrate, a package disposed on the package substrate, a lower lid disposed on the package substrate, and an upper lid disposed on the package and the lower lid. The package includes a first device die and a second device die adjacent to the first device die. The upper lid includes a first portion at least over the first die and a second portion over the lower lid. The structure further includes a thermal interface material disposed between the first portion of the upper lid and the package and a phase change material disposed between the second portion of the upper lid and the lower lid.

In accordance with yet another embodiment of the disclosure, a method of manufacturing a package structure is described. The method includes at least the following steps. A package is placed onto a substrate. A mechanical enhanced lid is attached over the substrate through an adhesive. A thermal enhanced lid is attached over the substrate and the package. A first portion of the thermal enhanced lid is attached to the package within an opening defined by the mechanical enhanced lid through a thermal interface material, and a second portion of the thermal enhanced lid is attached to the mechanical enhanced lid through a phase change material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate;
a semiconductor package disposed over the substrate;
a first lid structure disposed over the substrate, wherein the first lid structure comprises an opening exposing a region of the semiconductor package; and
a second lid structure disposed over the semiconductor package and the first lid structure, wherein a thermal interface material is disposed between the second lid structure and the semiconductor package, and a phase change adhesive is disposed between the second lid structure and the first lid structure.

2. The package structure of claim 1, wherein the first lid structure has a ring-shaped structure encircling the semiconductor package.

3. The package structure of claim 1, wherein the first lid structure comprises:
an outer peripheral portion; and
an inner peripheral portion connecting to the outer peripheral portion, wherein the opening is defined by the inner peripheral portion.

4. The package structure of claim 3, wherein a thickness of the inner peripheral portion is less than a thickness of the outer peripheral portion.

5. The package structure of claim 3, wherein the inner peripheral portion of the first lid structure comprises a recess, and a portion of the second lid structure is fit into the recess.

6. The package structure of claim 3, wherein the first lid structure further comprises a protruding portion connecting to the inner peripheral portion, and the protruding portion of the first lid structure protrudes into the second lid structure.

7. The package structure of claim 1, wherein the second lid structure comprises:
a central portion; and
an outer portion connecting to the central portion, wherein the central portion is fit into the opening of the first lid structure.

8. The package structure of claim 7, wherein the phase change adhesive is disposed between the outer portion of the second lid structure and the first lid structure.

9. The package structure of claim 7, wherein the second lid structure further comprises an overhang portion extend past an outer sidewall of the first lid structure.

10. The package structure of claim 1, further comprising:
a first back side metallization structure disposed on the semiconductor package;
a second back side metallization structure disposed on a portion of the second lid structure, where in the thermal interface material is between the first back side metallization structure and the second back side metallization structure.

11. The package structure of claim 1, wherein the phase change adhesive has a phase change temperature ranging from about 40° C. to about 60° C.

12. A structure, comprising:
a package substrate;
a package disposed on the package substrate, wherein the package comprises a first device die and a second device die adjacent to the first device die;
a lower lid disposed on the package substrate;
an upper lid disposed on the package and the lower lid, wherein the upper lid comprises a first portion at least over the first die and a second portion over the lower lid;
a thermal interface material disposed between the first portion of the upper lid and the package; and
a phase change material disposed between the second portion of the upper lid and the lower lid.

13. The package structure of claim 12, wherein the lower lid encircles the package.

14. The package structure of claim 12, wherein the lower lid comprises a first portion and a second portion connecting to the first portion, the first portion is disposed on the package substrate.

15. The package structure of claim 14, wherein the second portion of the lower lid comprises a recess, and the second portion of the upper lid is fit in the recess of the lower lid.

16. The package structure of claim 14, wherein the lower lid further comprises a third portion connecting to the second portion, and the third portion extends between the first portion of the upper lid and the second portion of the upper lid.

17. The package structure of claim 16, wherein the third portion is located over the second die of the package.

18. A method for forming a package structure, comprising:
placing a package onto a substrate;
attaching a mechanical enhanced lid over the substrate through an adhesive; and
attaching a thermal enhanced lid over the substrate and the package, wherein a first portion of the thermal enhanced lid is attached to the package within an opening defined by the mechanical enhanced lid through a thermal interface material, and a second portion of the thermal enhanced lid is attached to the mechanical enhanced lid through a phase change material.

19. The method of claim 18, further comprising forming a first back side metallization structure on a top surface of the package, a second back side metallization structure on a bottom surface of the first portion of the thermal enhanced lid, and the thermal interface material on the first back side metallization structure before attaching the thermal enhanced lid over the substrate and the package, wherein the thermal interface material is disposed between the first back side metallization structure and the second back side metallization structure after the thermal enhanced lid is attached over the substrate and the package.

20. The method of claim 18, further comprising performing a curing process to solidify the phase change material.
